(19) United States
(12) Patent Application Publication
(10) Pub. No.: US 2005/0158575 A1
(43) Pub. Date: Jul. 21, 2005

(54) Method for forming thin film on synthetic resin and multilayer film

(76) Inventors: Kenji Hattori, Osaka (JP); Etsuo Ogino, Osaka (JP)

Correspondence Address: SUGHRUE MION, PLLC, 2100 PENNSYLVANIA AVENUE, N.W., SUITE 800, WASHINGTON, DC, 20037, US

(21) Appl. No.: 10/495,077

(22) PCT Filed: Nov. 6, 2002
(86) PCT No.: PCT/JP02/11580

(30) Foreign Application Priority Data
Nov. 7, 2001 (JP) 2001-342018

(51) Int. Cl. B32B 15/08; C23C 14/32

(52) U.S. Cl. 428/626; 204/192.14

(57) ABSTRACT

An object of the invention, in the formation of a thin film on a synthetic resin, is to improve adhesiveness between the synthetic resin and the thin film by a relatively simple method. In the invention, a protective metallic layer is formed on a synthetic resin, and one thin film of (1) a semi-transmitting metallic mirror, (2) a total reflection metallic mirror, or (3) a transparent conductive film is formed. The material of the protective metallic layer is preferably selected from the group of Ti, Zr, Nb, Si, In, and Sn, and for sake of ensuring adhesiveness between the synthetic resin and the thin film, the film thickness of the protective metal layer is preferably 1 nm or more. Also, when the film thickness of the protective metallic layer is large, transmittance of the whole of the laminated film is lowered due to light absorption by the protective metallic layer, and hence, the film thickness of the protective metallic layer is preferably not more than 5 nm.

### TECHNICAL FIELD

The present invention relates to a method of forming a thin film composed of a metallic film, a conductive film, etc. on a synthetic resin with good adhesiveness and a laminated film obtained by that method, which is made of a synthetic resin and a thin film.

### BACKGROUND ART

When a thin film composed of a metallic film, a conductive film, etc. is formed on a synthetic resin composed of an electrode film-forming color filter for color display device, for the sake of ensuring adhesion of the thin film to the synthetic resin, a measure in which the surface of the synthetic resin is ionically irradiated prior to the formation of the thin film, thereby carbonizing a part of the surface of the synthetic resin to improve the adhesion to the thin film (hereinafter referred to “ionic cleaning process”) is known by the invention described in JP-A-10-10518 and so on.

Also, for the sake of forming a metallic film on a synthetic resin with good adhesiveness, there is known a method in which particles of a photocatalyst to decompose a synthetic resin to be used are carried on the synthetic resin, irradiated with ultraviolet rays, and then cleaned in water while imparting ultrasonic vibration, and after removing the particles of the photocatalyst on the foregoing surface, the resulting surface is subjected to sputtering, vacuum deposition, or electroless plating to coat a metallic film (JP-A-2001-11644).

In addition, in manufacturing optical information media such as laser videodiscs, there is a method in which a dilute gas is introduced between an anode installed with a synthetic resin substrate and a cathode as a counter electrode, a direct voltage of from 1,000 to 2,500 V is applied between the both electrodes, thereby generating plasma for from 1 to 20 seconds to preliminarily treat the surface of the resin substrate, and the surface of the synthetic resin substrate is subsequently subjected to sputtering to form a metallic reflecting film (JP-A-7-201087).

Since the foregoing ionic cleaning process involves a problem such that when the surface of the synthetic resin is excessively carbonized, the adhesiveness of the thin film is inversely lowered, this process is narrow in the range of the optimum condition for the carbonization treatment and is a hardly controllable technology.

That is, in the ionic cleaning process, the outermost surface of the synthetic resin is carbonized by ion irradiation. However, when treated excessively, the synthetic resin is physically and chemically damaged, and hence, adhesiveness between the synthetic resin and the thin film is lowered.

Also, the method in which the surface of the synthetic resin substrate is subjected to a combined treatment of ultraviolet treatment and ultrasonic treatment and a plasma treatment, and a thin film such as a metallic film is subsequently formed on the surface of the synthetic resin substrate by sputtering, etc. is a large-scale method regarding the preliminary treatment of the surface of the synthetic resin substrate and is not economical.

A problem of the invention is to provide a method of improving adhesion between a synthetic resin and a thin film by a relative simple method and a laminated film obtained by that method, which is made of a synthetic resin and a thin film.

### DISCLOSURE OF THE INVENTION

The foregoing problem of the invention is attained by the following construction of the invention.
(1) A method of forming a thin film on a synthetic resin, which comprises: a step of forming a protective metallic layer on a synthetic resin; and a step of forming one thin film of a semi-transmitting metallic mirror, a total reflection metallic mirror, and a transparent conductive film on the formed protective metallic layer.
(2) The method of forming a thin film on a synthetic resin according to the above item (1), wherein the protective metallic layer contains at least one of Ti, Zr, Nb, Si, In, and Sn.
(3) The method of forming a thin film on a synthetic resin according to the above item (1), whrerein the protective metallic layer is formed on the synthetic resin by sputtering.
(4) The method of forming a thin film on a synthetic resin according to the above item (1), wherein the thin film is formed on the protective metallic layer by sputtering.
(5) A laminated film comprising a protective metallic layer and one thin film of a semi-transmitting metallic mirror, a total reflection metallic mirror and a transparent conductive film, on a synthetic resin layer.
(6) The laminated film according to the above item (5), wherein the protective metallic layer contains at least one of Ti, Zr, Nb, Si, In, and Sn.
(7) The laminated film according to the above item (5), wherein the protective metallic layer has a film thickness of from 1 nm to 5 nm.

### BRIEF DESCRIPTION OF THE DRAWING

FIG. 1 is a sectional view in the case where an oxide film is formed on a protective metallic layer of the invention.

### DESCRIPTION OF REFERENCE NUMERALS AND SIGNS

1: Synthetic resin
2: Protective metallic layer
2′: Oxide layer
3: Oxide film

### BEST MODE FOR CARRYING OUT THE INVENTION

The foregoing problem of the invention can be solved by forming a protective metallic layer on a synthetic resin by sputtering.

As the synthetic resin of the invention, are enumerated the following three kinds.
(1) Light scattering synthetic resin film
(2) Overcoat on CF (color filter)
(3) Plastic substrate

Examples of the foregoing light scattering synthetic resin film (1) include ones in which a light scattering synthetic resin is coated on a glass substrate; and examples of the overcoat on CF (color filter) (2) include ones in which a reflection film, a color filter, and an overcoat are successively laminated on a glass substrate. Also, the plastic substrate (3) is a non-surface treated plastic substrate itself.

The light scattering synthetic resin is one in which, for example, an acrylic photocurable resin is used as the material, and unevennesses are formed on the surface by a photo-litho process to have a light scattering function.

The color filter is one that is generally formed by a “pigment dispersion process” or a “printing process”, and in which the raw material thereof is a natural high-molecular weight compound such as gelatin, casein, and glue, or a synthetic resin such as acrylic resins. Also, for the overcoat, synthetic resins such as acrylic based, epoxy based, and polyimide based resins are used as the material, and the overcoat is formed on the color filter for the purpose of protecting the color filter.

Examples of the plastic substrate include acrylic, epoxy based, and polyimide based substrates.

Also, examples of the thin film to be formed on the protective metallic layer include:
(1) A semi-transmitting metallic mirror (transmitting performance is important);
(2) A total reflection metallic mirror; and
(3) A transparent conductive film (transmitting performance is important).

Examples of the foregoing semi-transmitting metallic mirror (1) include ones in which a silicon oxide film, an aluminum film, and a silicon oxide film are successively laminated. Examples of the total reflection metallic mirror (2) include ones in which a silicon oxide film, an aluminum film, and a silicon oxide film are successively laminated. A difference between the forgoing (1) and (2) resides in film thickness of the metallic mirror and in whether or not light can transmit therethrough. Examples of the transparent conductive film include ones in which an indium oxide film is formed on a silicon oxide film.

In (1) and (3), the reasons why “transmitting performance is important” reside in the matter that in the case of semi-transmitting mirror, when a liquid crystal is brightly displayed by transmitting a backlight light source, the transmitting performance greatly influences lightness of the screen display; and that in the case of transparent conductive film, in order to display a liquid crystal, it is required to transmit light.

In the invention, for example, the protective metallic layer is formed on the surface of the synthetic resin by sputtering, thereby improving adhesion between the synthetic resin and the thin film.

By forming the protective metallic layer made of, as a material, a metal that is readily oxidized on the synthetic resin by sputtering, adhesiveness between the thin film formed as a film on the synthetic resin and the oxidized protective metallic layer increases, resulting in an improvement of the adhesiveness between the synthetic resin and the thin film. At this time, it is necessary to use a metal having good adhesiveness to the synthetic resin as the protective metallic layer material.

The material of the protective metallic layer is selected from Ti, Zr, Nb, Si, In, and Sn, and for the sake of ensuring the adhesiveness between the synthetic resin and the thin film, the protective metallic layer is required to have a film thickness of 1 nm or more. Also, when the film thickness of the protective metallic layer is large, transmittance of the whole of the laminated film is lowered due to light absorption by the protective metallic layer. Accordingly, the film thickness of the protective metallic layer is required to be not more than 5 nm.

The laminated film in which the thin film is formed on the synthetic resin via the protective metallic layer is used in electrode film-forming color filters for color display device, optical information media such as laser videodiscs, and the like.

(Action)

Mechanism of the improvement in the adhesiveness of the invention is assumed to reside in the following one. That is, oxygen plasma generated during forming the thin film such as an oxide film oxidizes and degrades the surface of the synthetic resin, whereby the adhesiveness between the thin film and the synthetic resin is lowered. However, by subjecting the protective metallic layer to film formation on the surface of the synthetic resin, the protective metallic layer prevents oxidation and degradation of the synthetic resin by oxygen plasma, whereby the adhesiveness between the thin film and the synthetic resin is improved.

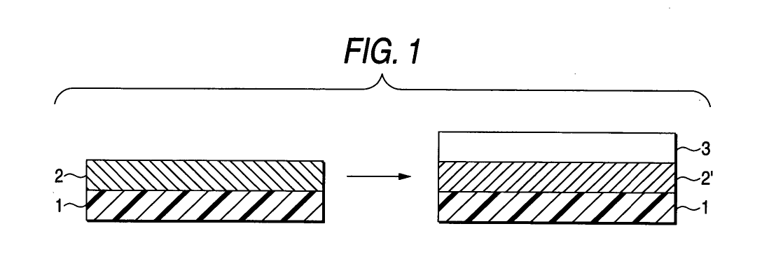

Also, as shown in FIG. 1, a protective metallic layer (such as a Ti layer) 2 on a synthetic resin 1 is oxidized when an oxide film (such as an SiO₂ film) 3 is subjected to film formation thereon. During this, since the film is very thin, the whole of the protective metallic layer 2 is oxidized to become an oxide layer (such as a TiO₂layer) 2′. Forthis reason, since light absorption by the protective metallic layer 2 can be ignored, it is possible to ensure transmitting characteristics of the thin film to be formed thereon.

From the foregoing results, in the case where the oxide film 3 such as an SiO₂ film is formed on the surface of the synthetic resin 1 by sputtering, etc., it is considered that the reason why film separation occurs so far between the synthetic resin 1 and the oxide film 3 resides in the oxidation and degradation of the surface of the synthetic resin by oxygen plasma.

The mode for carrying out the invention will be described.

### EXAMPLE 1

In this Example 1, an acrylic organic resin is used as a synthetic resin, and a total reflection aluminum mirror is formed as a thin film on the surface of the synthetic resin.

The construction of a film to be laminated is comprised of glass plate/synthetic resin film/Ti film/SiO₂ film/Al film/SiO₂ film.

Here, an alkali-free glass was used as a glass substrate, polymethyl methacrylate as an acrylic photocurable resin was coated on the glass substrate by spin coating, and after baking at 200° C. for one hour, an uneven shape was formed on the surface by a photo-litho process. On the resulting surface, were successively formed a Ti film (film thickness: 2.5 nm), an SiO₂ film (film thickness: 10 nm), an Al film (film thickness: 90 nm), and an SiO₂ film (film thickness: 25 nm) by sputtering.

The sputtering condition of the Ti film is 2 Pa for pressure (introduction of only Ar gas) and 0.3 kW for discharge electric power (dynamic rate: 1.1 nm·m/min).

The sputtering condition of the SiO₂ film is 0.6 Pa for pressure (gas composition: Ar/O₂=2/1) and 1.4 kW for discharge electric power (dynamic rate: 2.1 nm·m/min).

The sputtering condition of the Al film is 0.3 Pa for pressure (introduction of only Ar gas) and 4.1 kW for discharge electric power (dynamic rate: 37.8 nm·m/min).

### COMPARATIVE EXAMPLE 1

In this Comparative Example, a total reflection aluminum mirror is formed as a thin film on the surface of a synthetic resin in the same manner as in the foregoing Example 1.

The construction of a film to be laminated is comprised of glass plate/synthetic resin film/SiO₂ film (film thickness: 10 nm)/Al film (film thickness: 90 nm)/SiO₂ film (film thickness: 25 nm), and the surface of the synthetic resin was carbonized immediately before film formation of SiO₂ as a substrate by an ionic cleaning process under the following condition.

The ionic cleaning condition of the synthetic resin film is as follows:
Pressure: 4 Pa, gas composition: Ar/O₂=100/1, discharge electric power: 1.0 kW (RF), one minute, used target: SiO₂ (cathode).

The formation method of SiO₂ film (film thickness: 10 nm)/Al film (film thickness: 90 nm)/SiO₂ film (film thickness: 25 nm) is the same as in Example 1.

The results of adhesiveness test of the laminated films obtained in the foregoing Example 1 (using Ti layer) and Comparative Example 1 (conventional technology) are shown in Table 1.

TABLE 1

| | Immediately | | |
|---|---|---|---|
| | after film | After warm | After heating |
| | formation | water test | test |
| Example 1 | ∘ | ∘ | ∘ |
| Comparative | ∘ | x | x |
| Example 1 | | | |

∘: No peeling occurs.
Δ: Peeling occurs in less than 5 cells.
x: Peeling occurs in 5 or more cells.

As is clear from the results of Table 1, it is noted that in Example 1, the Ti film is present so that the adhesiveness between the synthetic resin layer and the total reflection aluminum mirror is improved as compared with Comparative Example 1.

### EXAMPLE 2

In this Example, an overcoat on a color filter is used as a synthetic resin, and an ITO film as a transparent conductive film is formed as a thin film on the surface of the foregoing synthetic resin.

The construction of a film to be laminated is comprised of glass plate/CF/overcoat (synthetic resin) film/Ti film/SiO₂ film/ITO film.

Here, an alkali-free glass was used as a glass substrate, and a color filter made of gelatin was formed on the glass substrate by a printing process to form a color filter-provided substrate. Trimelletic anhydride as a curing agent was added to polyglycidyl methacrylate as an acrylic organic resin, and the mixture was coated on the foregoing color filter-provided substrate by spin coating, followed by baking at 200° C. for one hour. On the resulting surface, were successively formed a Ti film (film thickness: 2.5 nm), an SiO₂ film (film thickness: 10 nm), and an ITO film (film thickness: 200 nm) by sputtering.

The sputtering condition of the Ti film is 2 Pa for pressure (introduction of only Ar gas) and 0.3 kW for discharge electric power (dynamic rate: 1.1 nm·m/min).

The sputtering condition of the SiO₂ film is 0.6 Pa for pressure (gas composition: Ar/O₂=2/1) and 1.4 kW for discharge electric power (dynamic rate: 2.1 nm·m/min).

The sputtering condition of the ITO film is 0.3 Pa for pressure (gas composition: Ar/O₂=99/1) and 5.5 kW for discharge electric power (dynamic rate: 32.4 nm·m/min).

### COMPARATIVE EXAMPLE 2

In this Comparative Example 2, an ITO film is formed as a thin film directly on an overcoat on CF in the same manner as in the foregoing Example 2.

The construction of a film to be laminated is comprised of glass plate/CF/overcoat (synthetic resin) film/SiO₂ film (film thickness: 10 nm)/ITO film (film thickness: 200 nm), and the surface of the synthetic resin was carbonized immediately before film formation of SiO₂ as a substrate by an ionic cleaning process under the following condition.

The formation method of SiO₂ film (film thickness: 10 nm)/ITO film (film thickness: 200 nm) is the same as in Example 2.

The ionic cleaning condition of the synthetic resin film is as follows:

Pressure: 4 Pa, gas composition: Ar/O₂=100/1, discharge electric power: 1.0 kW (RF), one minute, used target: SiO₂ (cathode).

The results of adhesiveness test of the laminated films obtained in the foregoing Example 2 (using Ti layer) and Comparative Example 2 (conventional technology) are shown in Table 2.

TABLE 2

| | Immediately | | |
|---|---|---|---|
| | after film | After warm | After heating |
| | formation | water test | test |
| Example 2 | ∘ | ∘ | ∘ |
| Comparative | ∘ | x | x |
| Example 2 | | | |

∘: No peeling occurs.
Δ: Peeling occurs in less than 5 cells.
x: Peeling occurs in 5 or more cells.

As is clear from the results of Table 2, it is noted that in Example 2, the Ti film is present so that the adhesiveness between the synthetic resin layer (overcoat on CF) and the ITO film is improved as compared with Comparative Example 2.

### EXAMPLE 3

The ground of setting the film thickness of the protective metallic layer of the invention will be described with reference to an example of using Ti as the protective metallic layer.

(1) A lower limit value of the film thickness of the protective metallic layer was set by changing the film thickness and confirming adhesiveness between the synthetic resin film and the thin film. The results are shown in Table 3.

TABLE 3

| | Set film thickness (nm) | | | | |
|---|---|---|---|---|---|
| | 0.5 | 1 | 3 | 5 | 10 |
| Immediately | Δ | ∘ | ∘ | ∘ | ∘ |
| after film | | | | | |
| formation | | | | | |
| After warm | x | ∘ | ∘ | ∘ | ∘ |
| water test | | | | | |
| After heating | x | ∘ | ∘ | ∘ | ∘ |
| test | | | | | |

*: The sputtering condition was the same as the condition of Example 1.
*: The film construction was the same as in “total reflection Al mirror” of Example 1.
*: The film thickness wad adjusted by discharge electric power.

Here, the film construction and the sputtering condition of the Ti film were the same as in Example 1. Also, the film thickness of the Ti film shown in Table 3 was adjusted by discharge electric power.

(2) An upper limit value of the film thickness of the protective metallic layer was set by changing the film thickness and confirming optical characteristics of the resulting laminated film. The results are shown in Table 4.

TABLE 4

| | Set film thickness (nm) | | | | | |
|---|---|---|---|---|---|---|
| | 0 | 1 | 3 | 5 | 6 | 10 |
| Absorbance | 23.0 | 23.0 | 23.0 | 23.0 | 28.3 | 35.9 |
| (%) | | | | | | |
| Judgment | — | OK | OK | OK | OK | OK |

*: Film construction, Glass/Ti/SiO₂/Al/SiO₂ (10/8/25) : semi-transmitting Al mirror

Here, the sputtering condition of the Ti film was the same as in Example 1. Also, the film thickness of the Ti film shown in Table 4 was adjusted by discharge electric power.

As described above, it is noted that in the case where it is demanded to ensure only the adhesiveness, there is a lower limit in the film thickness of the protective metallic film, whereas in the case where one attaches importance to adhesiveness and transmittance, there is an upper limit in addition to the lower limit; and it has become clear that when the film thickness of the Ti film falls within the range of from 1 nm to 5 nm, satisfactory results are revealed with respect to the adhesiveness and light absorbance.

The evaluation methods for the adhesiveness performed in the foregoing Examples and Comparative Examples are shown below.

The glass substrate having formed thereon the laminated film to be evaluated is evaluated by crosscutting and peeling immediately after the film formation and after the weather resistance test.

(a) Crosscutting:

The film surface is cut with 11 lines at an interval of 1 mm in each of the longitudinal and lateral directions and separated into pieces each having a size of 1 mm-square. Thus, 100 cells of 1 mm-square are prepared.

(b) Peeling:

After crosscutting, a cellophane adhesive tape (NITTO No. 29) is stuck on the film surface and then peeled apart at right angles while putting some snap, and a peeled portion is visually confirmed.

(c) Weather Resistance Test:

(1) Warm water test: The substrate is dipped in warm water of 80° C. for 30 minutes.
(2) Heating rest: The substrate is baked in the air at 240° C. for one hour.

### Industrial Applicability

According to the invention, it is possible to improve adhesiveness between a synthetic resin and a thin film and to maintain the adhesiveness of the thin film even when passing through a sever process (at high temperatures and in acid or alkaline solutions).

1. A method of forming a thin film on a synthetic resin, which comprises: a step of forming a protective metallic layer on a synthetic resin; and a step of forming one thin film of a semi-transmitting metallic mirror, a total reflection metallic mirror, and a transparent conductive film on the formed protective metallic layer.

2. The method of forming a thin film on a synthetic resin according to claim 1, wherein the protective metallic layer contains at least one of Ti, Zr, Nb, Si, In, and Sn.

3. The method of forming a thin film on a synthetic resin according to claim 1, whrerein the protective metallic layer is formed on the synthetic resin by sputtering.

4. The method of forming a thin film on a synthetic resin according to claim 1, wherein the thin film is formed on the protective metallic layer by sputtering.

5. A laminated film comprising a protective metallic layer and one thin film of a semi-transmitting metallic mirror, a total reflection metallic mirror and a transparent conductive film, on a synthetic resin layer.

6. The laminated film according to claim 5, wherein the protective metallic layer contains at least one of Ti, Zr, Nb, Si, In, and Sn.

7. The laminated film according to claim 5, wherein the protective metallic layer has a film thickness of from 1 nm to 5 nm.
